(19) United States
(12) Patent Application Publication
(10) Pub. No.: US 2008/0128015 A1
(43) Pub. Date: Jun. 5, 2008

(54) SOLAR COLLECTOR ARRANGEMENT WITH REFLECTING SURFACE

(75) Inventors: Daniel S. Shugar, San Bruno, CA (US); John Peurach, San Francisco, CA (US); Matthew P. Campbell, Berkeley, CA (US)

Correspondence Address: HAYNES BEFFEL & WOLFELD LLP, P O BOX 366, HALF MOON BAY, CA, 94019, US

(73) Assignee: PowerLight Corporation, Berkeley, CA (US)

(21) Appl. No.: 11/738,079

(22) Filed: Apr. 20, 2007

Related U.S. Application Data
(60) Provisional application No. 60/745,324, filed on Apr. 21, 2006.

(51) Int. Cl. H01L 31/052

(52) U.S. Cl. 136/246

(57) ABSTRACT

A PV assembly comprises a support assembly and first and second PV elements mounted to the support assembly with a gap separating the PV elements. The PV elements are bifacial PV elements having upper and lower active, energy-producing PV surfaces. The gap is a light-transmitting gap. The assembly also includes a light-reflecting surface carried by the support assembly beneath the PV elements and spaced apart from the PV elements so that light passing through the gap can be reflected back onto the lower PV surface of at least one of the PV elements.

### CROSS-REFERENCE TO OTHER APPLICATIONS

This application claims the benefit of Provisional Patent Application Number 60/745,324 filed 21 Apr. 2006 having the same title, attorney docket number PWRL 1040-3.

### FEDERALLY SPONSORED RESEARCH OR DEVELOPMENT

None.

### BACKGROUND OF THE INVENTION

This invention relates to solar energy collection, and in particular to a photovoltaic (PV) assembly using bifacial PV elements.

Photovoltaic arrays are used for a variety of purposes, including as a utility interactive power system, as a power supply for a remote or unmanned site, a cellular phone switch-site power supply, or a village power supply. These arrays can have a capacity from a few kilowatts to a hundred kilowatts or more, and are typically installed where there is a reasonably flat area with exposure to the sun for significant portions of the day. One type of PV element is constructed so as to have upper and lower active, energy-producing photovoltaic surfaces. These devices are typically referred to as bifacial PV elements or bifacial PV modules. In this way light striking both the upper and lower surfaces of the PV element can be used to create electricity thus increasing the efficiency of the device.

### BRIEF SUMMARY OF THE INVENTION

An example of a PV assembly comprises a support assembly and first and second PV elements mounted to the support assembly with a gap separating the PV elements. The PV elements are bifacial PV elements having upper and lower active, energy-producing PV surfaces. The gap is a light-transmitting gap. The assembly also includes a light-reflecting surface carried by the support assembly beneath the PV elements and spaced apart from the PV elements so that light passing through the gap can be reflected back onto the lower PV surface of at least one of the PV elements. In some examples the assembly includes a light-reflecting element mounted to the support assembly, wherein the light-reflecting element comprises the light-reflecting surface. The support assembly and the light-reflecting element may define an open region beneath the PV elements.

One of the problems with bifacial PV devices is that the increase in performance from the lower active surface is very dependent on the specific installation method and orientation. This has hindered the adoption of bifacial modules on a large scale. This invention makes the benefits of the bifacial module independent of these factors, providing dependable performance that can be quantified reliably for various applications.

Other features, aspects and advantages of the present invention can be seen on review the figures, the detailed description, and the claims which follow.

### BRIEF DESCRIPTION OF THE DRAWINGS

FIG. 1 is a top plan view of a first example of a bifacial PV assembly;

FIG. 2 is an isometric view of a portion of the PV assembly of FIG. 1;

FIG. 3 is an enlarged view of a portion of the PV assembly taken along line 3-3 of FIG. 1;

FIG. 4 is an isometric view of a second example of a bifacial PV assembly;

FIG. 5 is an enlarged cross-sectional view of a portion of the assembly of FIG. 4;

FIG. 6 is an isometric view of a third example of a bifacial PV assembly in which rows of the PV elements can track the sun;

FIG. 7 is an enlarged cross-sectional view of a portion of the PV assembly of FIG. 6 showing a row tilted towards the sun;

FIG. 8 is a partial cross-sectional view showing a stepper motor and pivot shaft;

FIG. 9 is an isometric view of a fourth example of a bifacial PV assembly with one end of the frame removed to illustrate the curved light-reflecting element;

FIG. 10 is an enlarged cross-sectional view of a portion of the assembly of FIG. 9;

FIG. 11 is a top plan view of a corner of a fifth example of a bifacial PV assembly in which gaps are created at the comers of adjacent PV elements; and

FIG. 12 is a partially exploded isometric view of a portion of the PV assembly of FIG. 11 showing individual reflective elements spaced apart below the corner gaps.

### DETAILED DESCRIPTION OF THE INVENTION

The following description will typically be with reference to specific structural embodiments and methods. It is to be understood that there is no intention to limit the invention to the specifically disclosed embodiments and methods but that the invention may be practiced using other features, elements, methods and embodiments. Preferred embodiments are described to illustrate the present invention, not to limit its scope, which is defined by the claims. Those of ordinary skill in the art will recognize a variety of equivalent variations on the description that follows. Like elements in various embodiments are commonly referred to with like reference numerals.

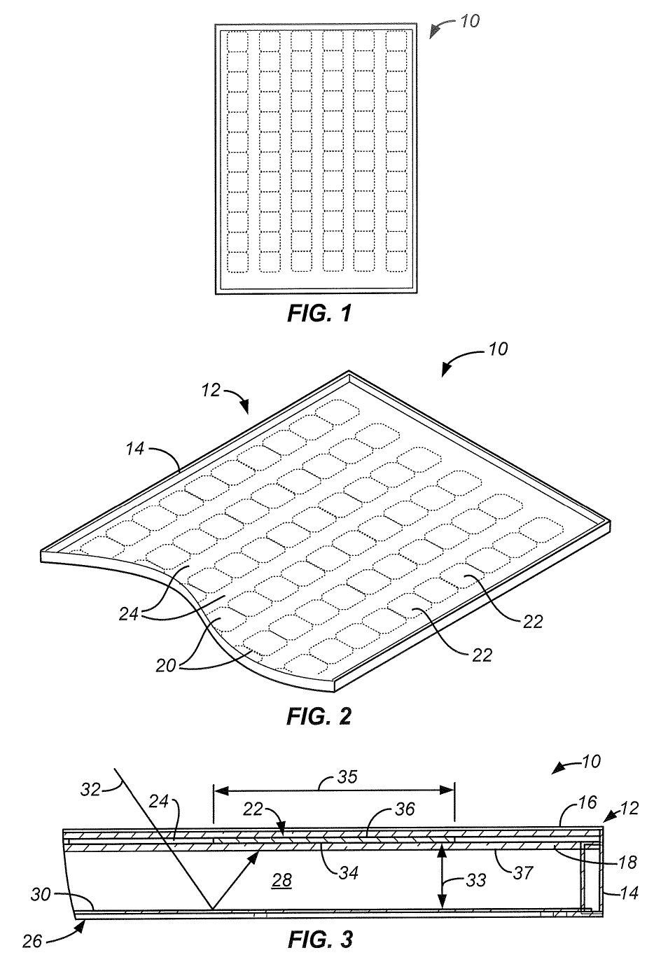

FIGS. 1-3 illustrate a first example of a bifacial PV assembly 10. Assembly 10 includes a support assembly 12 comprising a circumferentially extending frame 14 and first and second light-transmitting layers 16, 18. Assembly 10 also includes rows 20 of PV elements 22 captured between layers 16, 18. Rows 20 are spaced apart by light-transmitting gaps 24. Assembly 10 also includes a lower, light-reflecting element 26 mounted to frame 14 to create and open region 28 between second layer 18 and element 26. Light-reflecting element 26 extends beneath substantially all of the first and second light transmitting layers 16, 18. The upper surface 30 of element 26 is a light-reflecting surface so that light, exemplified by arrow 32 in FIG. 3, can pass through light-transmitting gaps 24, be reflected off of surface 30 and onto the lower surface 34 of PV elements 22. In this way PV elements 22 can transform light energy directly onto both their upper surfaces 36 and their lower surfaces 34 to create a more efficient device.

The cost of energy from a PV system will be largely affected by the installed cost and the efficiency of the PV assemblies. The installed cost of a PV system will be dependent on the cost of the PV elements, the cost of the other components making up a PV assembly, the cost of the mounting hardware, the installation cost, and a variety of other factors. Trade-offs must be made between competing priorities. In some cases, the highest priority is to install the most generating capacity in a given space. In other cases, it is more important to maximize the output of each PV assembly. Even if space constraints are unimportant, it is usually still desirable to maximize the output of PV assemblies so that the number of PV assemblies and the amount of mounting hardware required are kept to a minimum. For a bifacial module, if space constraints are not important, then it may be beneficial to increase the gaps between PV elements so that light reflected onto the lower surface of each PV element is maximized. If space is limited, then the best economics may come from keeping these gaps to a minimum.

The materials from which the elements of PV assembly 10 are made maybe conventional or unconventional. For example, first light-transmitting layer 16 may be made of, for example, glass or a laminate of layers of materials, and may or may not be covered with or treated with scratch-resistant or break-resistant films or coatings. Second layer 18 may be made of the same material as, or a different material from, first layer 16. However, second layer 18 will typically not include a scratch or break resistant film or coating. In some examples second layer may be omitted with lower surface 34 of PV elements 22 exposed directly to open region 28. Frame 14 is typically anodized aluminum; other suitable materials may be used as well. Light-reflecting element 26 may be made from a variety of materials having a highly light-reflecting upper surface 30, such as a polished metal sheet or a plastic sheet with a metallic upper surface. In addition, light-reflecting element 26 may be perforated or otherwise air permeable to help cool open region 28 and thus PV elements 22. Such openings may be evenly distributed or may to be more numerous or larger in regions where not as much light is expected to strike and be reflected onto lower surface 34.

In some examples the distance 33 between lower surface 34 of PV element 22 and reflective upper surface 30 is preferably at least about half the width 35 of PV element 22 for enhanced energy generation. The distance 33 between lower surface 34 of PV element 22 and reflective upper surface 30 is more preferably about equal to the width 35 of PV element 22 for efficient energy generation. In some examples width 35 can be made very small, about equal to the thickness of second light transmitting layer 18. By doing so, the lower surface 37 of the second light transmitting layer 18 and be made to be reflective so that layer 18 both supports and protects PV element 22 and also acts as the light reflecting element. In this example frame 14 can be made to essentially eliminate the open region 28 beneath second light transmitting layer 18, or frame 14 can be made larger than would otherwise be necessary to provide an open region 28 to help cool PV elements 22.

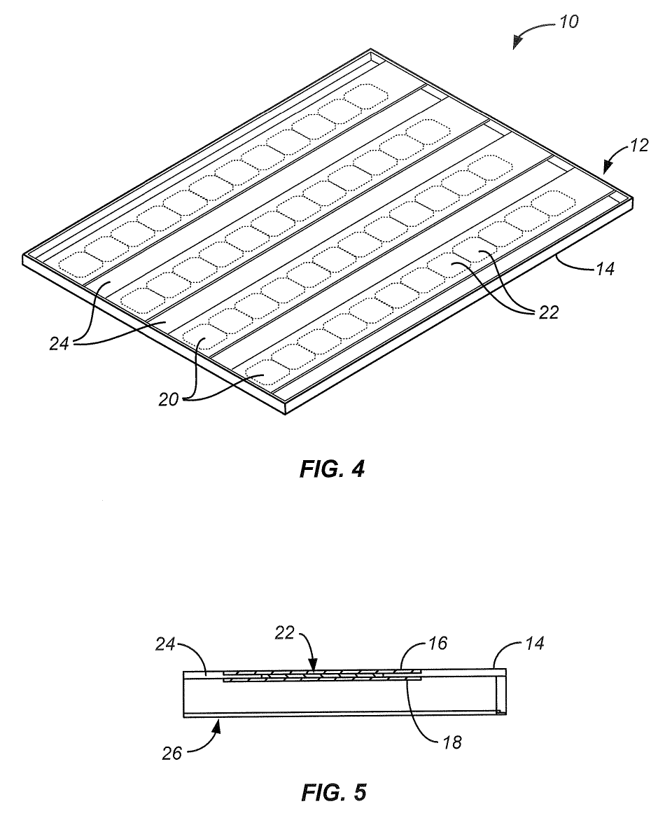

FIGS. 4 and 5 illustrate a further example of a bifacial PV assembly 10. In this example first and second light-transmitting layers 16, 18 are in the form of strips so that each has its own set of layers 16, 18 with an open gap 38 between each row 20. This arrangement permits both light and air to pass freely between rows 20 thus permitting airflow through open gaps 38 and between regions opposite lower and upper surfaces 34, 36 of PV elements 22. This helps to keep PV elements 22 cooler to help increase energy conversion efficiency and to help lengthen the life of the PV elements.

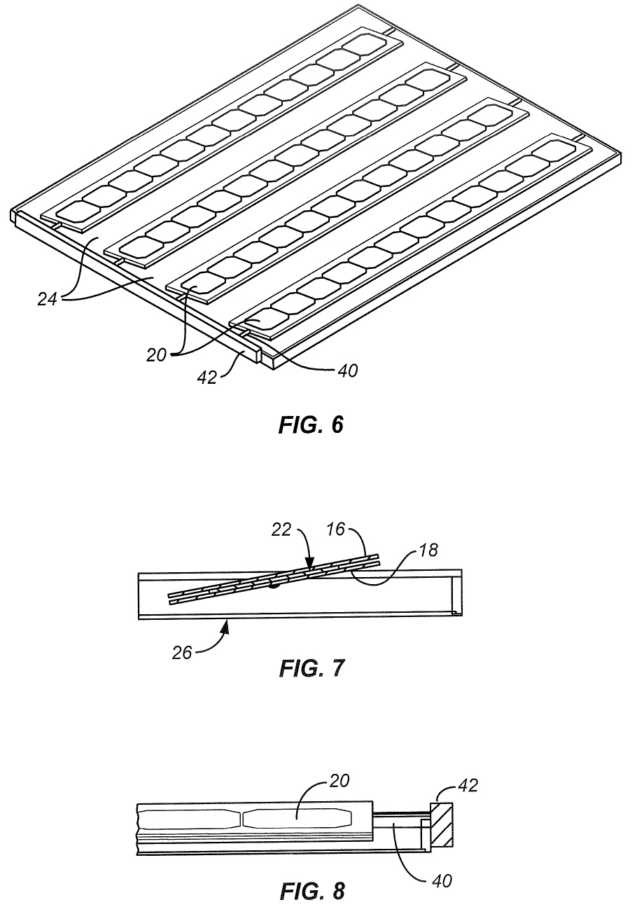

FIG. 6, 7 and 8 illustrate a further example of a bifacial PV assembly 10 in which the example of FIGS. 4 and 5 has been modified so that each row 20 is installed in frame 14 in such a manner to permit the rows to track the sun during the day. At the end of each row a pivot pin or shaft 40, or other suitable structure, is used to pivotally mount row 20 to frame 14. The drive mechanism used to pivot or tilt rows 20, so that they follow the sun between the morning and evening, can be conventional or unconventional in design. In one example a separate stepper motor 42 is mounted to pivot shaft 40 at one end of each row 20 so that each row is rotated individually. The force required to pivot each row 20 can be relatively small so that stepper motor 42 can be relatively inexpensive. A single controller, not shown, can be used to control stepper motor 42 for each row 20. The controller can provide a signal to each stepper motor 42 based upon, for example, the time of day or the sensed position of the sun. The connection between the controller and each stepper motor 42 can be a wired connection or a wireless connection. A wireless connection would be especially advantageous when a single controller is used to control stepper motors 42, or other drive mechanisms, for a number of PV assemblies 10. Also, a single drive mechanism can be used to rotate, for example, all of the rows 20 of one or more PV assemblies 10.

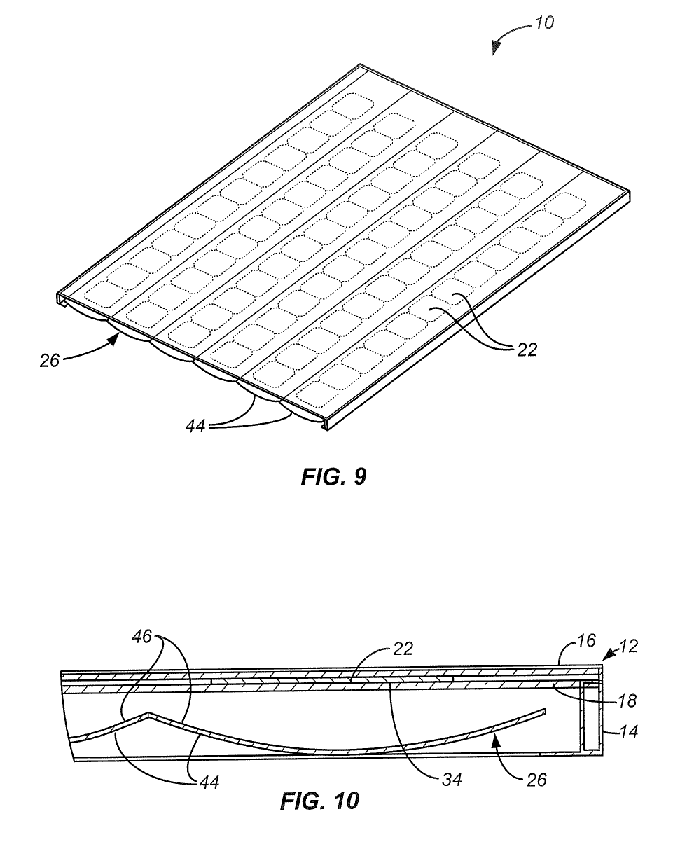

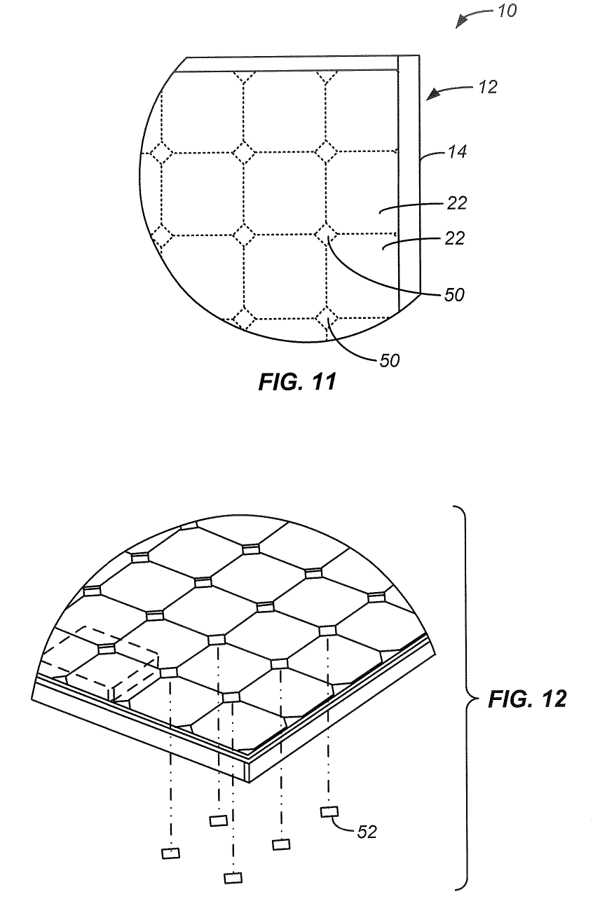

A further example is shown in FIGS. 9 and 10. In this example light-reflecting element 26 has a series of contoured, preferably concave, sections 44 to provide a series of concave upper reflecting surface segments 46 of upper surface 30. Each surface segment 46 extends along a row 20 of PV elements 22 and is generally centered beneath PV elements 22. The precise shape and size of reflecting surface segments 46 and the distance between the reflecting surface segments 46 and lower surface 34 of PV elements 22 can be optimized for different requirements.

For most applications, the optimal size of the PV elements will be the standard size that the manufacturer is set up to make. Other sizes will require additional processing which will add cost. However, this may be a worthwhile trade-off in some cases. The optimal ratio of PV element size to the size of the distance from the lower surface of the PV element to the reflecting surface can be determined through modeling or experimentation. This ratio will most likely remain constant, independent of application. In the extreme, the distance between the lower surface and the reflecting surface could become very small, providing a very compact product package, helping to minimize cost. In order to maintain the optimal ratio, the PV elements would have to be very small, which could increase cost. The gap between PV elements will vary depending on the overall goal for the system. If the goal is to maximize the output of each PV element, gap between PV elements will be made larger in order to allow more light to reach the rear surface of each PV element. If the goal is to fit the most generating capacity into the smallest space, then the gaps between PV elements will be made very small.

FIGS. 11 and 12 show portions of an assembly 10 in which rows 20 of bifacial PV elements 22 are spaced to effectively touch one another for enhanced packing density. PV elements 22 are shaped to create corner gaps 50 where the four corners of adjacent PV elements 22 meet. An amount, although a somewhat limited amount, of a bifacial energy production can be achieved by applying reflective elements 52 to the lower surface 37 of second light transmissive layer 18 directly beneath corner gaps 50. Reflective elements 52 are preferably the same size or somewhat larger than corner gaps 50. Alternatively, the entire lower surface 38 can be covered with a reflective material. In this example frame 14 can be made to essentially eliminate the open region 28 beneath second light transmitting layer 18, or frame 14 can be made larger than would otherwise be necessary to provide an open region 28 to help cool PV elements 22.

The above descriptions may have used terms such as above, below, top, bottom, over, under, et cetera. These terms are used to aid understanding of the invention are not used in a limiting sense.

While the present invention is disclosed by reference to the preferred embodiments and examples detailed above, it is to be understood that these examples are intended in an illustrative rather than in a limiting sense. It is contemplated that modifications and combinations will occur to those skilled in the art, which modifications and combinations will be within the spirit of the invention and the scope of the following claims.

Any and all patents, patent applications and printed publications referred to above are incorporated by reference.

1. A PV assembly comprising:
a support assembly;
first and second PV elements mounted to the support assembly with a gap separating the PV elements;
the PV elements being bifacial PV elements having upper and lower active, energy-producing PV surfaces;
the gap being a light-transmitting gap; and
a light-reflecting surface carried by the support assembly beneath the PV elements and spaced apart from the PV elements so that light passing through the gap can be reflected back onto the lower PV surface of at least one of the PV elements.

2. The PV assembly according to claim 1 further comprising a light-reflecting element mounted to the support assembly, wherein the light-reflecting element comprises the light-reflecting surface.

3. The PV assembly according to claim 2 wherein the support assembly and the light-reflecting element define an open region beneath the PV elements.

4. The PV assembly according to claim 3 wherein the gap is an open area to permit air to flow from a first location within the open region and opposite the lower PV surface, through the gap and to a second location opposite the upper PV surface.

5. The PV assembly according to claim 3 wherein the light-reflecting element is an air-permeable layer so to help cool the PV elements.

6. The PV assembly according to claim 1 wherein the PV elements have a width and the light-reflecting surface is spaced apart from the PV elements by a distance, the width being at least about one half the distance.

7. The PV assembly according to claim 1 wherein the PV elements have a width and the light-reflecting surface is spaced apart from the PV elements by a distance, the width being about equal to the distance.

8. The PV assembly according to claim 1 wherein the support assembly comprises a frame and a first light-transmitting support layer secured to and supported by the frame.

9. The PV assembly according to claim 8 where in the support assembly comprises a second light-transmitting support layer secured to and supported by the frame, the PV elements located between the light-transmitting support layers.

10. The PV assembly according to claim 9 wherein the second light-transmitting support layer has upper and lower surfaces, the upper surface facing the PV elements, the lower surface comprising the light-reflecting surface.

11. The PV assembly according to claim 10 wherein the PV elements have a width and the second light-transmitting support layer has a thickness of about equal to the width.

12. The PV assembly according to claim 10 further comprising an array of said PV elements, said array of PV elements having sides adjacent to one another and corner regions, the corner regions defining a plurality of the light-transmitting gaps.

13. The PV assembly according to claim 10 wherein the light-reflecting surface comprises a plurality of spaced-apart light-reflecting surfaces.

14. The PV assembly according to claim 8 wherein the first light-transmitting support layer covers the gap.

15. The PV assembly according to claim 8 wherein the light-reflecting element is mounted to the frame and extends beneath at least substantially the entire first light-transmitting support layer.

16. The PV assembly according to claim 8 wherein the first light-transmitting support layer comprises parallel, spaced apart, light-transmitting support layer strips having ends mounted to the frame and carrying said PV elements.

17. The PV assembly according to claim 16 wherein the support layer strips are non-rotatably mounted to the frame.

18. The PV assembly according to claim 16 wherein the support layer strips are pivotally mounted to the frame, and further comprising means for pivoting the support layer strips to permit the PV elements to track the sun.

19. The PV assembly according to claim 1 wherein the light-reflecting element is generally flat.

20. The PV assembly according to claim 1 wherein the light-reflecting element comprises contoured surface sections beneath the PV elements.

21. The PV assembly according to claim 1 wherein the light-reflecting element comprises concave surface sections beneath the PV elements.

22. A PV assembly comprising:
a support assembly comprising a frame and first and second light-transmitting support layers supported by the frame;
first and second PV elements mounted between the first and second light-transmitting support layers with a gap separating the PV elements;
the PV elements being bifacial PV elements having upper and lower active, energy-producing PV surfaces;
the gap being a light-transmitting gap;
a light-reflecting element mounted to the support assembly to extend beneath at least substantially the entire first light-transmitting support layer;
the support assembly and the light-reflecting element defining an open region beneath the PV elements;
the light-reflecting element mounted beneath the gap, whereby light passing through the gap can be reflected back onto the lower PV surface of at least one of the PV elements.
the light-reflecting element being an air-permeable layer so to help cool the PV elements.

23. The PV assembly according to claim 22 wherein the gap is an open area to permit air to flow from a first location within the open region and opposite the lower PV surface, through the gap and to a second location opposite the upper PV surface.

24. The PV assembly according to claim 22 wherein;
the support assembly comprises a frame and a first light-transmitting support layer supported by the frame;
the first light-transmitting support layer comprises parallel, spaced apart, light-transmitting support layer strips having ends mounted to the frame and carrying said PV elements.

25. The PV assembly according to claim 24 wherein the support layer strips are non-rotatably mounted to the frame.

26. The PV assembly according to claim 24 wherein the support layer strips are pivotally mounted to the frame, and further comprising means for pivoting the support layer strips to permit the PV elements to track the sun.
